(19) United States
(12) Patent Application Publication
(10) Pub. No.: US 2026/0082628 A1
(43) Pub. Date: Mar. 19, 2026

(54) SEMICONDUCTOR DEVICE INCLUDING A TRENCH GATE STRUCTURE

(71) Applicant: Infineon Technologies Austria AG, Villach (AT)

(72) Inventors: Brendan Toner, Villach (AT); Romain Esteve, München (DE); Martin Simon Weidl, München (DE)

(21) Appl. No.: 19/322,802

(22) Filed: Sep. 9, 2025

(30) Foreign Application Priority Data
Sep. 19, 2024 (DE) 102024208986.9

(51) Int. Cl. H10D 30/66; H01L 21/04; H10D 12/00; H10D 12/01; H10D 30/01; H10D 62/10; H10D 62/60; H10D 62/832

(52) U.S. Cl. CPC H10D 30/668; H10D 12/038; H10D 12/481; H10D 30/0291; H10D 62/103; H10D 62/124; H10D 62/60; H10D 62/8325; H10P 30/22

(57) ABSTRACT

A semiconductor device includes: a trench gate structure extending from a first surface into a silicon carbide semiconductor body along a vertical direction; and a body region of a first conductivity type adjoining a sidewall of the trench gate structure along a first lateral direction. The body region includes a first body sub-region adjoining the sidewall, a second body sub-region adjoining the sidewall, and a third body sub-region. The second body sub-region is arranged, along the first lateral direction, between the third body sub-region and the sidewall. An average net doping concentration along the first lateral direction is larger in the third body sub-region than in the second body sub-region. A degree of partial compensation of dopants of the first conductivity type by dopants of a second conductivity type is larger in the second body sub-region than in the third body sub-region.

### TECHNICAL FIELD

The present disclosure is related to a semiconductor device, in particular to a silicon carbide (SiC) semiconductor device including a trench gate structure.

### BACKGROUND

Technology development of SiC semiconductor devices including field effect transistor cells, e.g. insulated gate field effect transistors (IGFETs) such as metal oxide semiconductor field effect transistors (MOSFETs) or insulated gate bipolar transistors (IGBTs), aims at reducing an area-specific on-state resistance without adversely affecting a blocking voltage capability between source and drain or between emitter and collector. Although one device characteristic, for example the area-specific on-state resistance, may be improved by varying a certain device parameter, for example by increasing a drift zone doping concentration, this may lead to deterioration of another device characteristic, for example the blocking voltage capability. Thus, device parameters are designed during technology development based on a number of tradeoffs to be met in view of target device specifications.

There is a need to improve semiconductor devices based on silicon carbide.

### SUMMARY

An example of the present disclosure relates to a semiconductor device including a trench gate structure. The trench gate structure extends from a first surface into a silicon carbide semiconductor body along a vertical direction. The semiconductor device further includes a body region of a first conductivity type adjoining a sidewall of the trench gate structure along a first lateral direction. The body region includes a first body sub-region adjoining the sidewall. The body region further includes a second body sub-region adjoining the sidewall. The body region further includes a third body sub-region. The second body sub-region is arranged, along the first lateral direction, between the third body sub-region and the sidewall. An average net doping concentration along the first lateral direction is larger in the third body sub-region than in the second body sub-region. A degree of partial compensation of dopants of the first conductivity type by dopants of a second conductivity type is larger in the second body sub-region than in the third body sub-region.

Another example of the present disclosure relates to a method of manufacturing a semiconductor device. The method includes forming a trench gate structure extending from a first surface into a silicon carbide semiconductor body along a vertical direction. The method further includes forming a body region of a first conductivity type adjoining a sidewall of the trench gate structure along a first lateral direction. The body region includes a first body sub-region adjoining the sidewall. The body region further includes a second body sub-region adjoining the sidewall. The body region further includes a third body sub-region. The second body sub-region is arranged, along the first lateral direction, between the third body sub-region and the sidewall. An average net doping concentration along the first lateral direction is larger in the third body sub-region than in the second body sub-region. A degree of partial compensation of dopants of the first conductivity type by dopants of a second conductivity type is larger in the second body sub-region than in the third body sub-region.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of SiC semiconductor devices and methods of manufacturing SiC semiconductor devices and together with the description serve to explain principles of the embodiments. Further embodiments are described in the following detailed description and the claims.

FIG. 1 schematically and exemplarily illustrates a cross-sectional view of a configuration example of a SiC semiconductor device.

FIGS. 2 to 6 are graphs for schematically and exemplarily illustrating profiles of doping concentration or average doping concentrations along lines AA′ or BB′ of the SiC semiconductor device of FIG. 1.

FIG. 7 is an exemplary process illustration of manufacturing a SiC semiconductor device.

FIGS. 8A to 8D, 9A to 9F, 10A and 10B, 11A to 11F, and 12A to 12D are cross-sectional views for illustrating exemplary process features of manufacturing SiC semiconductor devices.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The Figures may illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations. Two directly adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa.

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A configuration example of a semiconductor device includes a trench gate structure extending from a first surface into a silicon carbide semiconductor body along a vertical direction. The semiconductor device further includes a body region of a first conductivity type adjoining a sidewall of the trench gate structure along a first lateral direction. The body region further includes a first body sub-region adjoining the sidewall. The body region further includes a second body sub-region adjoining the sidewall. The body region further includes a third body sub-region. The second body sub-region is arranged, along the first lateral direction, between the third body sub-region and the sidewall. An average net doping concentration along the first lateral direction is larger in the third body sub-region than in the second body sub-region. A degree of partial compensation of dopants of the first conductivity type by dopants of a second conductivity type is larger in the second body sub-region than in the third body sub-region.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET) or an insulated gate bipolar transistor (IGBT), for example. The semiconductor device may be a vertical semiconductor device having a load current flow between the first surface and a second surface opposite to the first surface along the vertical direction. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The semiconductor device may be based on a SiC semiconductor body from a crystalline SiC material. The crystalline SiC material may have a hexagonal crystal lattice, by way of example. For example, the semiconductor material may be 2H-SiC (SiC of the 2H polytype), 6H-SiC or 15R-SiC. According to an example, the semiconductor material is silicon carbide of the 4H polytype (4H-SiC). The SiC semiconductor body may include or consist of a semiconductor substrate having none, one or more than one semiconductor layers, e.g. epitaxially grown layers, thereon. One of the semiconductor layers may be a doped semiconductor layer of a current spread layer, for example.

The first surface may define a front surface or a top surface of the SiC semiconductor body, and the SiC semiconductor body may further include a second surface that may be a back surface or a rear surface of the SiC semiconductor body, for example. The SiC semiconductor body may be attached to a lead frame via the second surface, for example. Over the first surface of the SiC semiconductor body, bond pads may be arranged and bond wires may be bonded on the bond pads, for example.

For realizing a desired current carrying capacity, the SiC semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in a transistor cell area of the SiC semiconductor body. The transistor cell area may be an area where an emitter region of an IGBT (or a source region of a MOSFET) and a collector region of an IGBT (or a drain region of a MOSFET) are arranged opposite to one another along a vertical direction. In the transistor cell area, a load current may enter or exit the SiC semiconductor body of the semiconductor device, e.g. via contact plugs or contact lines on the top surface. The semiconductor device may further include an edge termination area that may include a termination structure. In a blocking mode or in a reverse biased mode of the semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

The trench gate structure may include a gate dielectric and a gate electrode, for example. The gate dielectric may include or consist of one layer or a combination of layers, e.g. a layer stack of dielectric layers, for example oxide layers such as thermal oxide layers or deposited oxide layers, e.g. tetraethyl orthosilicate (TEOS), undoped silicate glass (USG), phosphosilicate glass (PSG), boron silicate glass (BSP), borophosphosilicate glass (BPSG), nitride layers, high-k dielectric layers or low-k dielectric layers. A vertical extension of the trench gate structure may be in a range from 0.3 μm to 5 μm, e.g., in a range from 0.5 μm to 2 μm. Sidewalls of the trench gate structure may be perpendicular to the first surface or may taper with increasing distance to the first surface. A lateral width of the trench gate structure may be in a range from 500 nm to 5 μm, e.g., in a range from 1 μm to 3 μm. The gate electrode may include or consist of one electrode material or a combination of electrode materials, for example a doped semiconductor material (e.g., a degenerate doped semiconductor material) such as doped polycrystalline silicon, metal or metal compounds.

A doping concentration specifies a concentration of donors or a concentration of acceptors in a thermal equilibrium state. A net doping concentration specifies an absolute value of a net concentration obtained by subtracting the concentration of donors (being a concentration of positive ions) from the concentration of acceptors (being a concentration of negative ions). As an example, when the concentration of donors is N_{D} and the concentration of acceptors is N_{A}, the net doping concentration at any position is given as the absolute value of N_{D}−N_{A}. When the concentration of donors exceeds the concentration of acceptors, the net doping type is n-type. When the concentration of acceptors exceeds the concentration of donors, the net doping type is p-type. When the concentration of donors is N_{D} and the concentration of acceptors is N_{A}, and the concentration of acceptors exceeds the concentration of donors, i.e. N_{A}>N_{D}, the concentration of acceptors is partially compensated by the concentration of donors, and the degree of partial compensation is N_{D}/N_{A}. Likewise, when concentration of donors exceeds the concentration of acceptors, i.e. N_{D}>N_{A} the concentration of donors is partially compensated by the concentration of acceptors, and the degree of partial compensation is N_{A}/N_{D}.

Sub-regions of the body region, e.g. the first, second and third body sub-region, may define a continuous body region. For example, doping concentration profiles of body sub-regions adjoining one another along a specific direction may overlap along the specific direction.

SiC semiconductor devices described herein allow for a number of technical benefits, e.g. in view of the configurations of the body region. For example, the electrical performance of the devices may be improved by enabling a high body doping concentration without negatively affecting the channel region. This may result in reduced Drain Induced Barrier Lowering (DIBL) and/or improved Short Circuit Withstand Time (SCWT). For example, the high body doping concentration, e.g. in the third body sub-region, may support shielding the gate dielectric of the trench gate structure from high electric fields since less of the body region is depleted with higher drain voltage. The counter-doping in the second body sub-region avoids a negative impact of the high body doping concentration on the channel region, e.g. undesired threshold voltage increase. Thus, electric shielding and channel characteristics may be independently optimized or improved.

For example, an average net doping concentration along the vertical direction may be larger in the third body sub-region than in the first body sub-region. For example, a vertical doping concentration profile of the body region may include at least one peak in the third body sub-region. A doping concentration of the at least one peak in the third body sub-region may be by a factor of 1.5, or 2, or 2.5 larger than a maximum doping concentration in the first body sub-region. This may allow for improving shielding of the gate dielectric of the trench gate structure from high electric fields, for example.

For example, the third body sub-region may have a larger extension along the first lateral direction than the second body sub-region. For example, the extension of the second body sub-region along the first lateral direction may be in a range from 50 nm to 500 nm, or from 100 nm to 300 nm, for example. The lateral extension of the third body sub-region along the first lateral direction may be by a factor of 2, or 3 or 5 larger than the lateral extension of the second body sub-region along the first lateral direction. This may allow for independently improving channel properties as well as shielding of the gate dielectric of the trench gate structure from high electric fields, for example.

For example, the dopants of the second conductivity type causing the partial compensation in the second body sub-region may be absent in the third body sub-region. The dopants of the second conductivity type, corrected by a background doping of the semiconductor body, causing the partial compensation in the second body sub-region may be absent in the third body sub-region. Absence of the dopants of the second conductivity type causing the partial compensation in the second body sub-region may be achieved by implanting the dopants of the second conductivity type into the second body sub-region but not into the third body sub-region, e.g. by a tilted ion implantation process though a sidewall of a gate trench and/or by a masked ion implantation process through the first surface.

For example, the dopants of the second conductivity type causing the partial compensation in the second body sub-region may be absent in a portion of the first body sub-region that adjoins the third body sub-region. The dopants of the second conductivity type, corrected by a background doping of the semiconductor body, causing the partial compensation in the second body sub-region may be absent in a portion of the first body sub-region that adjoins the third body sub-region. Absence of the dopants of the second conductivity type causing the partial compensation in the second body sub-region may be achieved by implanting the dopants of the second conductivity type into the second body sub-region but not into the portion of the first body sub-region that adjoins the third body sub-region, e.g. by a tilted ion implantation process though a sidewall of a gate trench.

For example, the semiconductor device may further include a source region of the second conductivity type adjoining the sidewall of the trench gate structure. The source region may adjoin the first body sub-region along the vertical direction. The first body sub-region may adjoin each of the second body sub-region and the third body sub-region along the vertical direction.

For example, the semiconductor device may further include a drift structure of the second conductivity type. The drift structure may be arranged, along the vertical direction, between the body region and a second surface of the silicon carbide semiconductor body. Each of the second body sub-region and the third body sub-region may adjoin the drift structure along the vertical direction. For example, each of the second body sub-region and the third body sub-region may adjoin a current spread region of the drift structure along the vertical direction. The current spread region may have a larger doping concentration than a drift region of the drift structure. The drift region may adjoin a bottom side of the current spread region, for example.

For example, along the vertical direction, a net doping concentration profile includes at least one peak in the third body sub-region. A net doping concentration at the at least one peak is larger than any net doping concentration in the first body sub-region, for example.

For example, a doping concentration profile of dopants of the first conductivity type may be constant along the first lateral direction along a section extending from inside the third body sub-region to inside the second body sub-region. Thus, the smaller net doping concentration in the third body sub-region compared with the second body-sub-region may be primarily caused by counter-doping, for example.

For example, along the vertical direction, a doping concentration profile of dopants of the first conductivity type includes a least one peak in the third body sub-region.

For example, the semiconductor device may further include a shielding region of the first conductivity type. The shielding region may adjoin at least a part of a bottom side of the trench gate structure. The shielding region may further adjoin a sidewall of the trench gate structure that is opposite to the sidewall of the trench gate structure where the channel region is formed.

Details with respect to structure, or function, or technical benefit of features described above with respect to a semiconductor device such as a FET, or IGBT likewise apply to the exemplary methods described further below. Processing the SiC semiconductor body may comprise one or more optional additional features corresponding to one or more aspects mentioned in connection with the proposed concept or one or more examples described above or below.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

An example of a method of manufacturing a semiconductor device includes forming a trench gate structure extending from a first surface into a silicon carbide semiconductor body a vertical direction. The method further includes forming a body region of a first conductivity type adjoining a sidewall of the trench gate structure along a first lateral direction. The body region includes a first body sub-region adjoining the sidewall. The body region further includes a second body sub-region adjoining the sidewall. The body region further includes a third body sub-region. The second body sub-region is arranged, along the first lateral direction, between the third body sub-region and the sidewall. An average net doping concentration along the first lateral direction is larger in the third body sub-region than in the second body sub-region. A degree of partial compensation of dopants of the first conductivity type by dopants of a second conductivity type is larger in the second body sub-region than in the third body sub-region.

For example, the method may further include forming a shielding mask pattern on the first surface of the silicon carbide semiconductor body. The method may further include forming a shielding region of the first conductivity type by introducing dopants of the first conductivity type through an opening in the shielding mask pattern. The method may further include forming at least part of the third body sub-region by introducing dopants of the first conductivity type through the opening in the shielding mask pattern by a tilted ion implantation process.

For example, forming the trench gate structure and forming the body region may include forming a first part of the body region by introducing dopants of the first conductivity type through the first surface into the silicon carbide semiconductor body by at least two ion implantation processes having different ion implantation energies. Thereafter, the method may further include forming a trench structure mask pattern on the first surface of the silicon carbide semiconductor body. The method may further include forming a second part of the body region by introducing dopants of the second conductivity type into the second body sub-region through an opening of the trench structure mask pattern. Thereafter, the method may further include forming a part of the trench structure by etching a gate trench into the silicon carbide semiconductor body through the opening of the trench structure mask pattern.

For example, forming the trench gate structure and forming the body region may include forming a first part of the body region by introducing dopants of the first conductivity type through the first surface into the silicon carbide semiconductor body by an ion implantation process. Thereafter, the method may further include forming a trench structure mask pattern on the first surface of the silicon carbide semiconductor body. The method may further include forming a second part of the body region by introducing dopants of the second conductivity type into the second body sub-region through an opening of the trench structure mask pattern. Thereafter, the method may further include reducing a width of the opening by expanding the trench structure mask pattern with a sidewall spacer. The method may further include forming a part of the trench structure by etching a gate trench through the opening of the trench structure mask pattern including the sidewall spacer.

For example, forming the trench gate structure and forming the body region may include forming a first part of the body region by introducing dopants of the first conductivity type through the first surface into the silicon carbide semiconductor body by at least two ion implantation processes having different ion implantation energies. Thereafter, the method may further include forming a trench structure mask pattern on the first surface of the silicon carbide semiconductor body. The method may further include forming a part of the trench structure by etching a gate trench into the silicon carbide semiconductor body through the opening of the trench mask pattern. Thereafter, the method may further include forming a second part of the body region by introducing dopants of the second conductivity type into the second body sub-region through a sidewall of the gate trench by a tilted ion implantation process.

For example, the method may further include forming a shielding mask pattern on the first surface of the silicon carbide semiconductor body. The method may further include forming a shielding region of the first conductivity type by introducing dopants of the first conductivity type through an opening in the mask pattern.

For example, the third body sub-region may be formed with a larger extension along the first lateral direction than the second body sub-region.

For example, the method may further include forming an ion implantation mask on the first surface of the silicon carbide semiconductor body. The method may further include forming a current spread region of the second conductivity type by introducing dopants of the second conductivity type through the opening in the ion implantation mask. Thereafter, the method may further include forming the trench gate structure. The trench gate structure may include a process of forming a gate trench into the semiconductor body by at least one etch process. The at least one etch process may remove part of the dopants previously introduced for forming the current spread region, for example.

For example, the method may further include forming a part of the body region by introducing dopants of the first conductivity type through the opening in the ion implantation mask.

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

Details with respect to structure, or function, or technical benefit of features described above with respect to a semiconductor device such as a FET, or IGBT likewise apply to the exemplary methods described further below. Processing the SiC semiconductor body may comprise one or more optional additional features corresponding to one or more aspects mentioned in connection with the proposed concept or one or more examples described above or below.

In some of the illustrated examples, n-channel FETs or IGBTs are illustrated. However, the examples described herein may also be applied to p-channel devices, e.g. p-channel MOSFETs or p-channel IGBTs. For example, dopants in a semiconductor body comprising SiC may include Al, B, Be, Ga, or any combination thereof for p-type doping, and N, P, or any combination thereof for n-type doping.

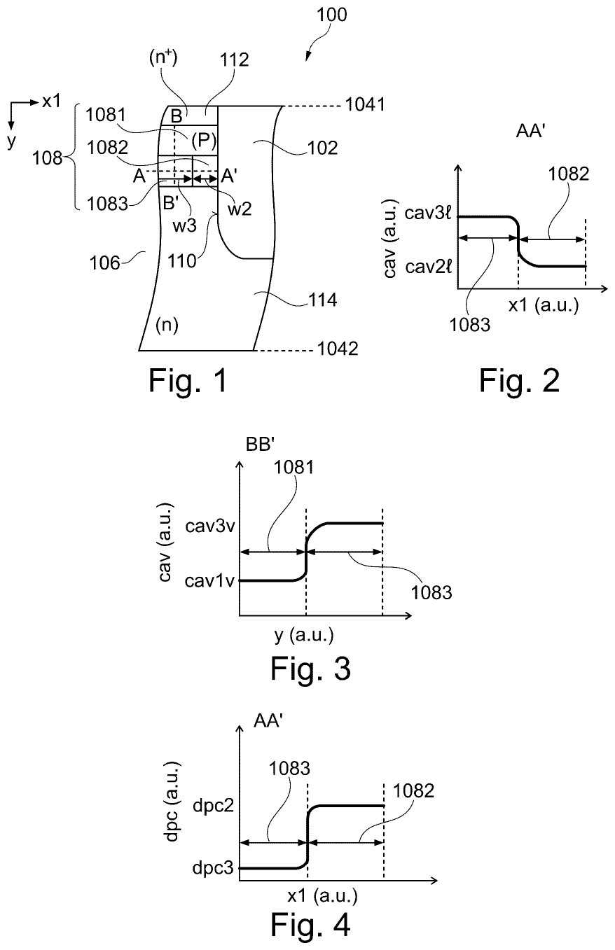

The schematic cross-sectional view of FIG. 1 illustrates a configuration example of a SiC semiconductor device 100. The graphs illustrated in FIGS. 2 to 6 are based on the configuration example of FIG. 1 and exemplify doping concentration profiles or relations along cut lines AA′ or BB′ of FIG. 1.

Referring to the configuration example of a SiC semiconductor device 100 in FIG. 1, a trench gate structure 102 extends, along a vertical direction y, into a silicon carbide semiconductor body 106 from a first surface 1041. The first surface 1041, e.g. a front surface, is arranged opposite to a second surface 1042 of the SiC semiconductor body 106.

A p-doped body region 108 adjoins a sidewall 110 of the trench gate structure 102 along a first lateral direction x1. The first lateral direction x1 may be perpendicular to the vertical direction y. The body region 108 includes a first body sub-region 1081 adjoining the sidewall 110. The first body sub-region 1081 further adjoins a bottom side of an n⁺-doped source region 112. The body region 108 further includes a second body sub-region 1082 adjoining the sidewall 110. The second body sub-region 1082 adjoins a bottom side of the first body sub-region 1081. The body region 108 further includes a third body sub-region 1083. The second body sub-region 1082 is arranged, along the first lateral direction x1, between the third body sub-region 1083 and the sidewall 110. The third body sub-region 1083 may have a larger extension w3 along the first lateral direction x1 than the extension w2 of the second body sub-region 1082.

Referring to the graph of FIG. 2, an average net doping concentration cav is schematically and exemplarily illustrated along line AA′ of FIG. 1 that extends in the first lateral direction x1. The average net doping concentration cav corresponds to an average value cav3l of the net doping concentration along an extension of the third body sub-region 1083 in the first lateral direction x1. The average net doping concentration cav further corresponds to an average value cav2l of the net doping concentration along an extension of the second body sub-region 1082 in the first lateral direction x1. The average net doping concentration cav3l in the third body sub-region 1083 is larger than the average net doping concentration cav2l in the second body sub-region 1082.

Referring to the graph of FIG. 3, an average net doping concentration cav is schematically and exemplarily illustrated along line BB′ of FIG. 1 that extends in the vertical direction y. The average net doping concentration cav corresponds to an average value cav1v of the net doping concentration along an extension of the first body sub-region 1081 in the vertical direction y. The average net doping concentration cav further corresponds to an average value cav3v of the net doping concentration along an extension of the third body sub-region 1083 in the vertical direction y. The average net doping concentration cav3v in the third body sub-region 1083 is larger than the average net doping concentration cav1v in the first body sub-region 1081. For example, the average net doping concentration cav1v in the first body sub-region 1081 may be equal to or approximately that of the average net doping concentration cav2l in the second body sub-region 1082.

Referring to the graph of FIG. 4, a degree of partial compensation dpc of p-type dopants by n-type dopants is schematically and exemplarily illustrated along line AA′ of FIG. 1 that extends in first lateral direction x1. The degree of partial compensation dpc has a value dpc3 in the third body sub-region 1083. The degree of partial compensation dpc has a value dpc2 in the second body sub-region 1082. The degree dpc2 of partial compensation of p-type dopants by n-type dopants in the second body sub-region 1082 is larger than the degree dpc3 of partial compensation of p-type dopants by n-type dopants in the third body sub-region 1083. The degree dpc3 may be influenced by an n-type background doping the semiconductor body 106, for example.

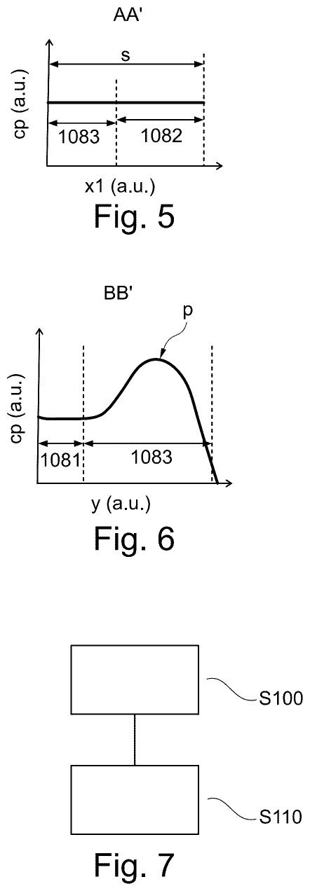

Referring to the graph of FIG. 5, a doping concentration profile of p-type dopants cp is schematically and exemplarily illustrated along line AA′ of FIG. 1 that extends in the first lateral direction x1. The doping concentration profile of p-type dopants cp is constant along the first lateral direction x1 along a section s extending from inside the third body sub-region 1083 to inside the second body sub-region 1082. Apart from process-related impacts, e.g. a pile-up effect, the doping concentration profile of p-type dopants cp may be constant along an overall extension of the third body sub-region 1083 and the second body sub-region 1082 along the first lateral direction x1.

Referring to the graph of FIG. 6, a doping concentration profile of p-type dopants cp is schematically and exemplarily illustrated along line BB′ of FIG. 1 that extends in the vertical direction y. The doping concentration profile of p-type dopants cp includes a peak P in the third body sub-region 1083.

An example of a method of manufacturing a semiconductor device is illustrated by referring to the flowchart of FIG. 7.

Process feature S100 includes forming a trench gate structure extending from a first surface into a silicon carbide semiconductor body along a vertical direction.

Process feature S110 includes forming a body region of a first conductivity type adjoining a sidewall of the trench gate structure along a first lateral direction, wherein the body region includes a first body sub-region adjoining the sidewall, a second body sub-region adjoining the sidewall, and a third body sub-region, the second body sub-region being arranged, along the first lateral direction, between the third body sub-region and the sidewall. An average net doping concentration along the first lateral direction is larger in the third body sub-region than in the second body sub-region, and a degree of partial compensation of dopants of the first conductivity type by dopants of a second conductivity type is larger in the second body sub-region than in the third body sub-region.

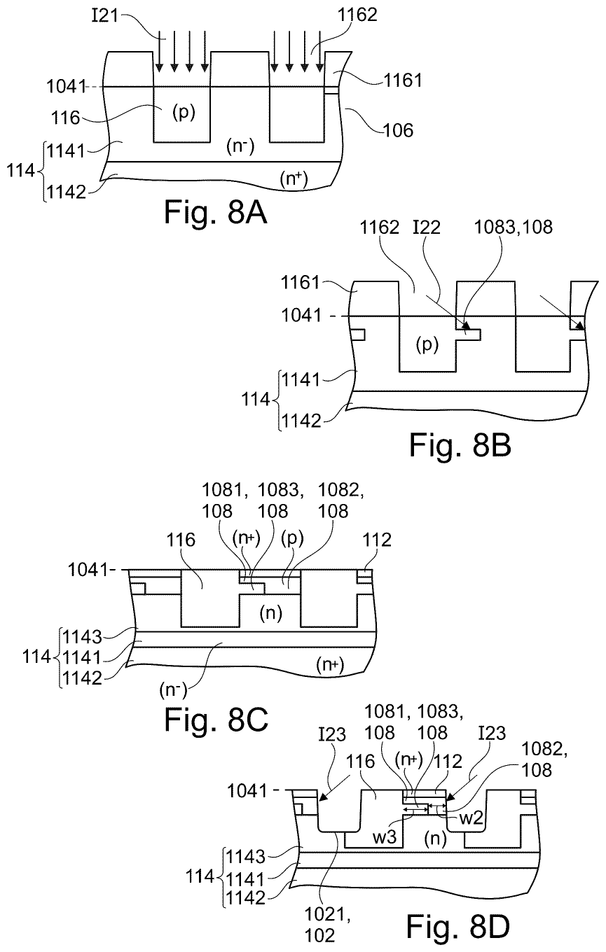

The schematic cross-sectional views of FIGS. 8A to 8D schematically and exemplarily illustrate process features for forming a SiC semiconductor device according to the examples disclosed herein.

Referring to FIG. 8A, a shielding mask pattern 1161, e.g. a hard mask pattern such as a TEOS mask pattern, is formed on the first surface 1041 of the silicon carbide semiconductor body 106. A drift structure 114 in the SiC semiconductor body 106 includes an n⁻-doped drift region 1141 on an n⁺-doped substrate 1142. A p-doped shielding region 116 is formed in the SiC semiconductor body 106 by introducing p-type dopants through an opening 1162 in the shielding mask pattern 1162 by an ion implantation process I21.

Referring to FIG. 8B, at least part of the third body sub-region 1083 of the body region 108 is formed by introducing p-type dopants through the opening 1162 in the shielding mask pattern 1161 by a tilted ion implantation process I22.

Referring to FIG. 8C, an n⁺-doped source region 112, the p-doped first body sub-region 1081, parts of the p-doped second and third body sub-regions 1082, 1083 and an n-doped current spread region 1143 as part of the drift structure 114 are formed by introducing n-and p-type dopants into the SiC semiconductor body 106 by a plurality of ion implantation processes using at least one mask pattern (mask pattern(s) not illustrated in FIG. 8C).

Referring to FIG. 8D, a gate trench 1021 of a gate trench structure 102 is formed in the SiC semiconductor body 106 from the first surface 1041, e.g. by at least one etch process using an etch mask pattern (etch mask pattern is not illustrated in FIG. 8D). A second part of the second body sub-region 1082 is formed by introducing n-type dopants into the second body sub-region 1082 through a sidewall of the gate trench 1021, e.g. by a tilted ion implantation process I23. By introducing the n-type dopants in the second body sub-region 1082, a degree of partial compensation of p-type dopants by n-type is set larger in the second body sub-region 1082 than in the third body sub-region 1083.

Further process features, e.g. formation of a gate dielectric, a gate electrode, a wiring area over the first surface, rear side processes follow.

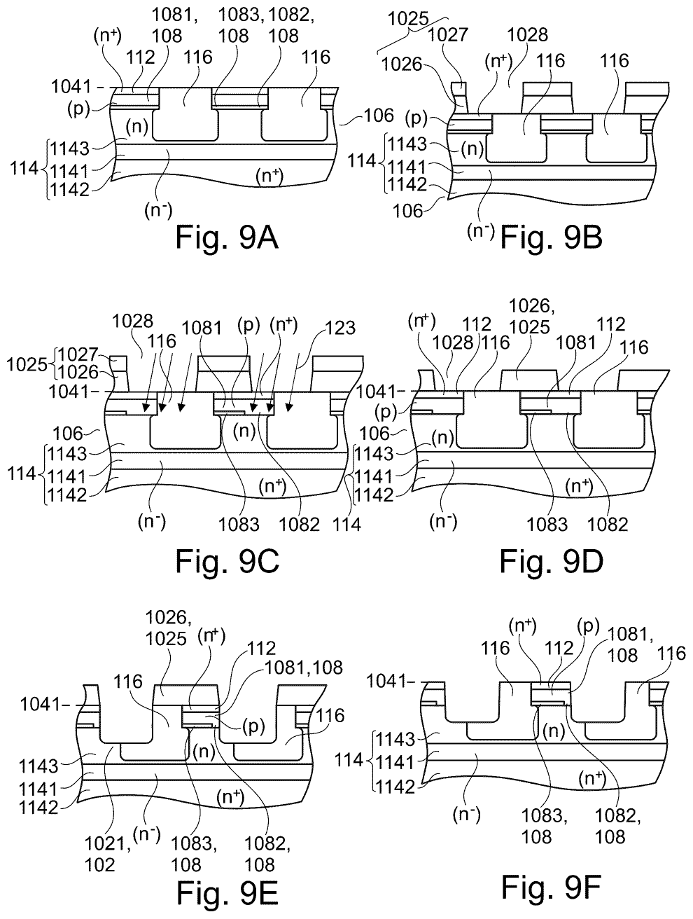

The schematic cross-sectional views of FIGS. 9A to 9F schematically and exemplarily illustrate process features for forming a SiC semiconductor device according to the examples disclosed herein.

Referring to FIG. 9A, the p-doped shielding region 116, the n⁺-doped source region 112, the p-doped first body sub-region 1081, the p-doped third body sub-region 1083, a part of the second body sub-region 1082, and the n-doped current spread region 1143 as part of the drift structure 114 are formed by introducing n- and p-type dopants into the SiC semiconductor body 106 by a plurality of ion implantation processes using at least one mask pattern (mask pattern(s) not illustrated in FIG. 9A).

Referring to FIG. 9B, a trench structure mask pattern 1025 is formed on the first surface 1041 of the silicon carbide semiconductor body 106. For example, the trench structure mask pattern 1025 includes a trench structure hard mask pattern 1026 and a trench structure resist mask pattern 1027. An opening 1028 is formed in the trench structure mask pattern 1025.

Referring to FIG. 9C, a second part of the second body sub-region 1082 is formed by introducing n-type dopants into the second body sub-region 1082 through the opening 1028 of the trench structure mask pattern 1025, e.g. by a tilted ion implantation process I23. By introducing the n-type dopants in the second body sub-region 1082, a degree of partial compensation of p-type dopants by n-type is set larger in the second body sub-region 1082 than in the third body sub-region 1083.

Referring to FIGS. 9D and 9E, the trench structure resist mask pattern 1027 is removed, and the gate trench 1021 of the gate trench structure 102 is formed in the SiC semiconductor body 106 from the first surface 1041, e.g. by at least one etch process using the remaining trench structure hard mask pattern 1026 as an etch mask.

Referring to FIG. 9F, the trench structure hard mask pattern 1026 is removed.

Further process features, e.g. formation of a gate dielectric, a gate electrode, a wiring area over the first surface, rear side processes follow.

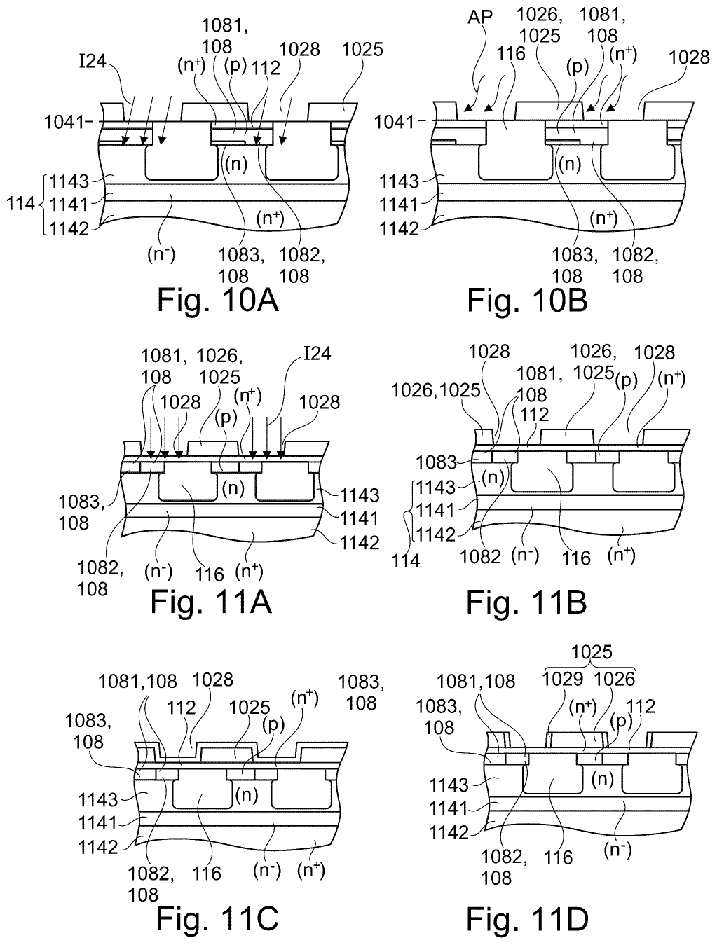

The schematic cross-sectional views of FIGS. 10A and 10B illustrate a process modification of process features illustrated with reference to FIG. 9C.

Other than in FIG. 9C and by referring to FIG. 10A, the second part of the second body sub-region 1082 is formed by introducing n-type dopants, e.g. by an ion implantation process I24, into the second body sub-region 1082 through the opening 1028 of the trench structure mask pattern 1025 after the trench structure resist mask pattern 1027 is removed. Referring to FIG. 10B, an activation anneal process AP for electrically activating dopants is carried out.

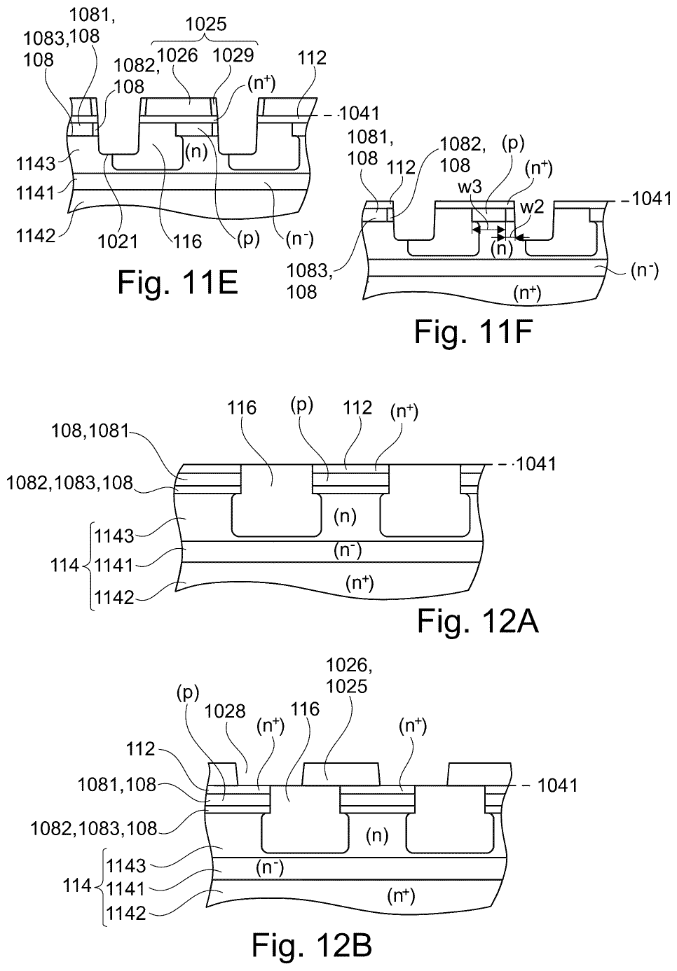

The schematic cross-sectional views of FIGS. 11A to 11D schematically and exemplarily illustrate process features for forming a SiC semiconductor device according to the examples disclosed herein.

Process features similar to FIGS. 9A and 9B are carried out based on the trench structure hard mask pattern 1026. Thereafter and by referring to FIG. 11A, a second part of the body region 108 is formed by introducing n-type dopants into the second body sub-region 1082 and a part of the first body sub-region 1081 through the opening 1028 of the trench structure mask pattern 1025. By introducing the n-type dopants in the second body sub-region 1082, a degree of partial compensation of p-type dopants by n-type is set larger in the second body sub-region 1082 than in the third body sub-region 1083.

Referring to FIG. 11B, an activation anneal process for electrically activating dopants is carried out.

Referring to FIGS. 11C and 11D a width of the opening 1028 of the trench structure mask pattern 1025 is reduced by expanding the trench structure mask pattern 1025 with a sidewall spacer 1029 using a spacer layer deposition and etch process.

Referring to FIG. 11E, the gate trench 1021 of the gate trench structure 102 is formed in the SiC semiconductor body 106 from the first surface 1041, e.g. by at least one etch process using the trench structure mask pattern 1025 as an etch mask.

Referring to FIG. 11F, the trench structure mask pattern 1025 is removed. By applying the self-aligned spacer process using the sidewall spacer 1029, the width w2 of the second body sub-region 1082 may be accurately defined as it depends on the width of the sidewall spacer 1029.

Further process features, e.g. formation of a gate dielectric, a gate electrode, a wiring area over the first surface, rear side processes follow.

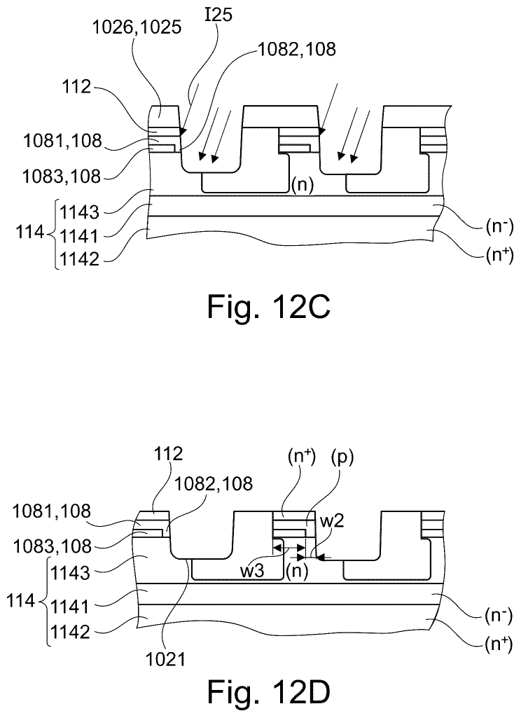

The schematic cross-sectional views of FIGS. 12A to 12D schematically and exemplarily illustrate process features for forming a SiC semiconductor device according to the examples disclosed herein.

Referring to FIG. 12A, the p-doped shielding region 116, the n⁺-doped source region 112, the p-doped first body sub-region 1081, the p-doped third body sub-region 1083, a part of the p-doped second body sub-region 1082, and the n-doped current spread region 1143 as part of the drift structure 114 are formed by introducing n-and p-type dopants into the SiC semiconductor body 106 by a plurality of ion implantation processes using at least one mask pattern (mask pattern(s) not illustrated in FIG. 12A).

Referring to FIG. 12B, the trench structure mask pattern 1025 is formed on the first surface 1041 of the silicon carbide semiconductor body 106. For example, the trench structure mask pattern 1025 includes a trench structure hard mask pattern 1026. An opening 1028 is formed in the trench structure mask pattern 1025.

Thereafter and by referring to FIG. 12C, n-type dopants are introduced into the second body sub-region 1082 through the opening 1028 of the trench structure mask pattern 1025 by an ion implantation process I25. By introducing the n-type dopants in the second body sub-region 1082, a degree of partial compensation of p-type dopants by n-type is set larger in the second body sub-region 1082 than in the third body sub-region 1083.

Referring to FIG. 12D, the trench structure mask pattern 1025 is removed.

Further process features, e.g. formation of a gate dielectric, a gate electrode, a wiring area over the first surface, rear side processes follow.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a trench gate structure extending from a first surface into a silicon carbide semiconductor body along a vertical direction;
a body region of a first conductivity type adjoining a sidewall of the trench gate structure along a first lateral direction,
wherein the body region includes a first body sub-region adjoining the sidewall, a second body sub-region adjoining the sidewall, and a third body sub-region,
wherein the second body sub-region is arranged, along the first lateral direction, between the third body sub-region and the sidewall,
wherein an average net doping concentration along the first lateral direction is larger in the third body sub-region than in the second body sub-region, and
wherein a degree of partial compensation of dopants of the first conductivity type by dopants of a second conductivity type is larger in the second body sub-region than in the third body sub-region.

2. The semiconductor device of claim 1, wherein an average net doping concentration along the vertical direction is larger in the third body sub-region than in the first body sub-region.

3. The semiconductor device of claim 1, wherein the third body sub-region has a larger extension along the first lateral direction than the second body sub-region.

4. The semiconductor device of claim 1, wherein the dopants of the second conductivity type causing the partial compensation in the second body sub-region are absent in the third body sub-region.

5. The semiconductor device of claim 1, wherein the dopants of the second conductivity type causing the partial compensation in the second body sub-region are absent in a portion of the first body sub-region that adjoins the third body sub-region.

6. The semiconductor device of claim 1, further comprising:
a source region of the second conductivity type adjoining the sidewall of the trench gate structure,
wherein the source region adjoins the first body sub-region along the vertical direction, and
wherein the first body sub-region adjoins each of the second body sub-region and the third body sub-region along the vertical direction.

7. The semiconductor device of claim 1, further comprising:
a drift structure of the second conductivity type arranged, along the vertical direction, between the body region and a second surface of the silicon carbide semiconductor body,
wherein each of the second body sub-region and the third body sub-region adjoins the drift structure along the vertical direction.

8. The semiconductor device of claim 1, wherein along the vertical direction, a net doping concentration profile includes at least one peak in the third body sub-region, and a net doping concentration at the peak is larger than any net doping concentration in the first body sub-region.

9. The semiconductor device of claim 1, wherein a doping concentration profile of dopants of the first conductivity type is constant along the first lateral direction along a section extending from inside the third body sub-region to inside the second body sub-region.

10. The semiconductor device of claim 1, wherein along the vertical direction, a doping concentration profile of dopants of the first conductivity type includes a least one peak in the third body sub-region.

11. The semiconductor device of claim 1, further comprising:
a shielding region of the first conductivity type,
wherein the shielding region adjoins at least a part of a bottom side of the trench gate structure.

12. A method of manufacturing a semiconductor device, the method comprising:
forming a trench gate structure extending from a first surface into a silicon carbide semiconductor body along a vertical direction; and
forming a body region of a first conductivity type adjoining a sidewall of the trench gate structure along a first lateral direction,
wherein the body region includes a first body sub-region adjoining the sidewall, a second body sub-region adjoining the sidewall, and a third body sub-region,
wherein the second body sub-region is arranged, along the first lateral direction, between the third body sub-region and the sidewall,
wherein an average net doping concentration along the first lateral direction is larger in the third body sub-region than in the second body sub-region,
wherein a degree of partial compensation of dopants of the first conductivity type by dopants of a second conductivity type is larger in the second body sub-region than in the third body sub-region.

13. The method of claim 12, further comprising:
forming a shielding mask pattern on the first surface of the silicon carbide semiconductor body;
introducing dopants of the first conductivity type through an opening in the shielding mask pattern, to form a shielding region of the first conductivity type; and
introducing dopants of the first conductivity type through the opening in the shielding mask pattern by a tilted ion implantation process, to form at least part of the third body sub-region.

14. The method of claim 12, wherein forming the trench gate structure and forming the body region comprises:
introducing dopants of the first conductivity type through the first surface into the silicon carbide semiconductor body by at least two ion implantation processes having different ion implantation energies, to form a first part of the body region;
thereafter forming a trench structure mask pattern on the first surface of the silicon carbide semiconductor body;
introducing dopants of the second conductivity type into the second body sub-region through an opening of the trench structure mask pattern, to form a second part of the body region; and
thereafter etching a gate trench into the silicon carbide semiconductor body through the opening of the trench structure mask pattern, to form a part of the trench structure.

15. The method of claim 14, further comprising:
forming a shielding mask pattern on the first surface of the silicon carbide semiconductor body; and
introducing dopants of the first conductivity type through an opening in the shielding mask pattern, to form a shielding region of the first conductivity type.

16. The method of claim 12, wherein forming the trench gate structure and forming the body region comprises:
introducing dopants of the first conductivity type through the first surface into the silicon carbide semiconductor body by an ion implantation process, to form a first part of the body region;
thereafter forming a trench structure mask pattern on the first surface of the silicon carbide semiconductor body;
introducing dopants of the second conductivity type into the second body sub-region through an opening of the trench structure mask pattern, to form a second part of the body region;
thereafter reducing a width of the opening by expanding the trench structure mask pattern with a sidewall spacer; and
etching a gate trench through the opening of the trench structure mask pattern including the sidewall spacer, to form a part of the trench structure.

17. The method of claim 16, further comprising:
forming a shielding mask pattern on the first surface of the silicon carbide semiconductor body; and
introducing dopants of the first conductivity type through an opening in the shielding mask pattern, to form a shielding region of the first conductivity type.

18. The method of claim 12, wherein forming the trench gate structure and forming the body region comprises:
introducing dopants of the first conductivity type through the first surface into the silicon carbide semiconductor body by at least two ion implantation processes having different ion implantation energies, to form a first part of the body region;
thereafter forming a trench structure mask pattern on the first surface of the silicon carbide semiconductor body;
etching a gate trench into the silicon carbide semiconductor body through an opening of the trench mask pattern, to form a part of the trench structure; and
thereafter introducing dopants of the second conductivity type into the second body sub-region through a sidewall of the gate trench by a tilted ion implantation process, to form a second part of the body region.

19. The method of claim 18, further comprising:
forming a shielding mask pattern on the first surface of the silicon carbide semiconductor body; and
introducing dopants of the first conductivity type through an opening in the shielding mask pattern, to form a shielding region of the first conductivity type.

20. The method of claim 12, wherein the third body sub-region is formed with a larger extension along the first lateral direction than the second body sub-region.

21. The method of claim 12, further comprising:
forming an ion implantation mask at the first surface of the silicon carbide semiconductor body;
introducing dopants of the second conductivity type through an opening in the ion implantation mask, to form a current spread region of the second conductivity type; and
thereafter forming the trench gate structure.

22. The method of claim 21, further comprising:
introducing dopants of the first conductivity type through the opening in the ion implantation mask, to form a part of the body region.
